(19) United States
(12) Patent Application Publication
(10) Pub. No.: US 2011/0089443 A1
(43) Pub. Date: Apr. 21, 2011

(54) Packaging Structure of AC light-emitting diodes

(75) Inventor: Hui-Wen Hsu, Danshui Township (TW)

(73) Assignee: Forward Electronics Co., Ltd., Taipei City (TW)

(21) Appl. No.: 12/801,704

(22) Filed: Jun. 22, 2010

(30) Foreign Application Priority Data
Oct. 15, 2009 (TW) 098219015

(51) Int. Cl. H01L 33/62; H01L 33/48

(52) U.S. Cl. 257/93; 257/99; 257/E33.056; 257/E33.066

(57) ABSTRACT

A packaging structure of AC LEDs is provided, which comprises: a carrier containing a positive electrode connecting end, and a negative electrode connecting end; an AC LED module disposed on the carrier, wherein the AC LED module electrically connects to the positive electrode connecting end and the negative electrode connecting end of the carrier; and a die-bonding insulating layer disposed between the AC LED module and the carrier.

### BACKGROUND OF THE INVENTION

1. Field of the Invention

The present invention relates to a packaging structure of alternating current light-emitting diodes (AC LEDs) and, more particularly, to a packaging structure of AC LEDs with good reliability.

2. Description of Related Art

FIG. 1 is a perspective view of a conventional packaging structure of an LED. The conventional packaging structure of the LED comprises: a carrier 10, and an LED die 11. The LED die 11 electrically connects to a positive electrode connecting end 101 and a negative electrode connecting end 102 of the carrier 10 through conductive wires 12, and the LED die 11 is bound on the carrier through a conductive silver paste 13.

When the LED die 11 is bound on the carrier 10 by use of the conductive silver paste 13, the conductive silver paste 13 may cover the edge of the LED die 11, and even totally cover the surface of the LED die 11. In this case, partial surface of the LED die 11 is covered, so the light output region is decreased and the light emitting efficiency is reduced. Further, when the amount of the conductive silver paste 13 is too much to adhere on the circuit layer of the LED die 11, it may cause the problem of current-leakage and increased power consumption, and the reliability of the products may be decreased.

In addition, when the diameter of an Ag particle in the conductive silver paste 13 is big, the gap between the LED die 11 and the carrier 10 may be increased, and the LED die 11 cannot adhere on the carrier 10 tightly. Hence, the bonding between the LED die and the heat dissipating base (not shown in the figure) of the carrier is not good enough. In addition, the Ag particles with big diameters may cause holes to be formed in the conductive silver paste. When the product is baked at high temperature, the conductive silver paste may become cracked, and the heat dissipating efficiency may be decreased.

Currently, the aforementioned packaging structure of the LED is applied on a direct current LED, and there is no problem of high voltage. However, when the aforementioned packaging structure of the LED is applied on an AC LED, the insulating effect of the conductive silver paste is not good enough. Hence, the product cannot pass the impact test of high voltage, so the reliability of the packaging structure of LED has to be improved.

Therefore, it is desirable to provide a packaging structure of AC LEDs, which can pass the impact test of high voltage, and thus be commercialized.

### SUMMARY OF THE INVENTION

The object of the present invention is to provide a packaging structure of AC LEDs, which can pass the impact test of high voltage, and can prevent the problem of current-leakage and increased power consumption.

To achieve the object, the packaging structure of AC LEDs includes a carrier containing a positive electrode connecting end, and a negative electrode connecting end; an AC LED module disposed on the carrier, wherein the AC LED module electrically connects to the positive electrode connecting end and the negative electrode connecting end of the carrier; and a die-bonding insulating layer disposed between the AC LED module and the carrier.

In the packaging structure of the AC LEDs of the present invention, not only the AC LED module can be bound on the carrier, but also the problem that conductive silver paste covers the surfaces of LED dies can be solved to increase the light emitting efficiency through the intrinsic cohesion of the die-bonding insulating layer. In addition, when the packaging structure of the AC LEDs of the present invention is connected to a grid, it can pass the impact test of high voltage and fit the standard in reliability such as UL, CE, TUV, FCC, CSA, PSE, and BSMI. Also, the packaging structure of the AC LEDs of the present invention can accomplish the requirement of environmental protection, energy conservation, and usage safety. In addition, when an external high voltage is applied on the die-bonding insulating layer of the present invention, the die-bonding insulating layer can be prevented from being punctured. Hence, the packaging structure of the AC LEDs of the present invention can keep its electrical stability, and the lifetime thereof can be improved. Furthermore, the die-bonding insulating layer has great insulation ability. Even when an operator touches the packaging structure of the AC LEDs of the present invention incautiously, the problem of damage or fatal defect can be eliminated. Hence, the packaging structure of the AC LEDs of the present invention exhibits great safety of operation. In addition, the die-bonding insulating layer used in the packaging structure of the AC LEDs of the present invention can keep good reliability and stability under a broad range of temperature. Hence, the adhesion between the AC LED module and the carrier can be maintained under broad range of temperature, so the stability of the products can be improved.

According to the packaging structure of AC LEDs of the present invention, the AC LED module may comprise plural LED dies, which connect to each other in series. In addition, the die-bonding insulating layer may comprise plural die-bonding regions, and each die-bonding region respectively corresponds to one LED die.

According to the packaging structure of AC LEDs of the present invention, the AC LED module electrically connects to the positive electrode connecting end and the negative electrode connecting end through conductive wires: Also, the LED dies connect in series to each other through conductive wire. Herein, the conductive wire can be any metallic wire used in the art. Preferably, the conductive wire is an Au wire.

In addition, the packaging structure of AC LEDs of the present invention may further comprise a heat dissipating unit, wherein the heat dissipating unit is disposed under the AC LED module, and the die-bonding insulating layer is arranged between the heat dissipating unit and the AC LED module. Herein, the heat dissipating unit can be any heat dissipating unit made of metal, which is conventionally used in the art. Preferably, the heat dissipating unit is a heat dissipating Cu unit.

Furthermore, according to the packaging structure of AC LEDs of the present invention, the thickness of the LED dies may be 100 μm or more. Preferably, the thickness of the LED dies is 100˜200 μm. Further, the thickness of the die-bonding insulating layer may be 50˜120 μm. Preferably, the thickness of the die-bonding insulating layer is 50˜80 μm.

In addition, according to the packaging structure of AC LEDs of the present invention, the die-bonding insulating layer is a die-bonding silicone layer, preferably. The color of the die-bonding insulating layer is creamy white translucent, the hardness is 50˜60 Shore D, the modules of elasticity 170˜190 N/mm², the density is 1.0˜1.2 g/cm³ (25° C.), the light transmissivity is 1.5˜3% (400 nm/2 mm), the linear expansion coefficient is 200˜230 ppm (25-150° C.), the thermal conductivity is 0.15˜0.22 W/m·K, and the dielectric breakdown voltage is 23˜28 kV/mm.

### BRIEF DESCRIPTION OF THE DRAWINGS

FIG. 1 is a perspective view of a conventional packaging structure of LEDs; and

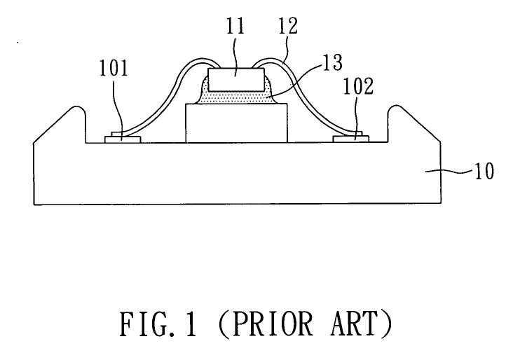

FIG. 2 is a perspective view of a packaging structure of AC LEDs of a preferred embodiment of the present invention.

### DETAILED DESCRIPTION OF THE PREFERRED EMBODIMENT

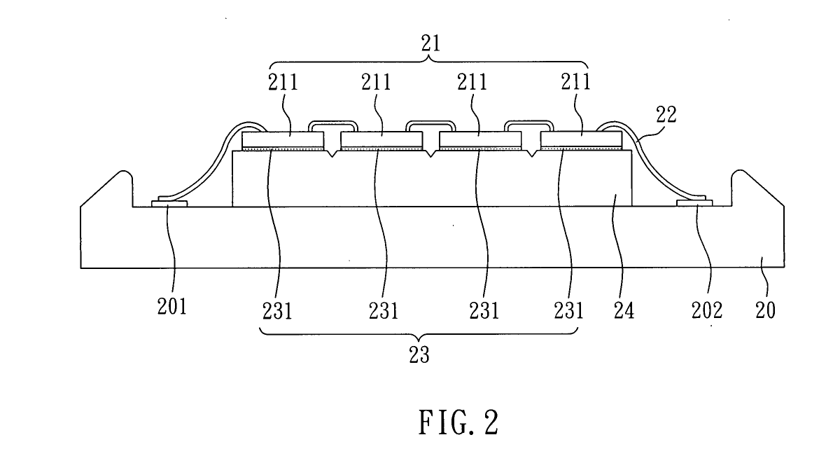

FIG. 2 is a perspective view of a packaging structure of AC LEDs of a preferred embodiment of the present invention.

As shown in FIG. 2, the packaging structure of AC LEDs of the present embodiment comprises: a carrier 20, an AC LED module 21, and a die-bonding insulating layer 23. Herein, the carrier 20 contains a positive electrode connecting end 201, and a negative electrode connecting end 202. The AC LED module 21 is disposed on the carrier 20, wherein the AC LED module 21 electrically connects to the positive electrode connecting end 201 and the negative electrode connecting end 202 of the carrier 20. The die-bonding insulating layer 23 is disposed between the AC LED module 21 and the carrier 20.

In the present embodiment, the die-bonding insulating layer 23 is a die-bonding silicone layer. In addition, the thickness of the die-bonding insulating layer 23 may be 50˜120 μm. In the present embodiment, the thickness of the die-bonding insulating layer 23 is 80

Additionally, in the present embodiment, the AC LED module 21 comprises plural LED dies 211, which connect in series to each other through conductive wires 22. Also, the AC LED module 21 electrically connects to the positive electrode connecting end 201 and the negative electrode connecting end 202 through conductive wires 22. In the present embodiment, the conductive wires 22 are Au wires.

In the present embodiment, the die-bonding insulating layer 23 comprises plural die-bonding regions 231, and each die-bonding region 231 respectively corresponds to one LED die 211.

In addition, the packaging structure of AC LEDs of the present embodiment further comprises a heat dissipating unit 24, wherein the heat dissipating unit 24 is disposed under the AC LED module 21, and the die-bonding insulating layer 23 is arranged between the heat dissipating unit 24 and the AC LED module 21. In the present embodiment, the heat dissipating unit 24 is a heat dissipating Cu unit.

In order to overcome the problem of high voltage consumption, the thickness of the LED dies 211 of the present embodiment may be 100˜200 μm. In the present embodiment, the thickness of the LED dies 211 is 100 μm.

Hence, the die-bonding insulating layer 23 can endure high voltage. Also, the increase on the thickness of the LED dies 211, i.e. the increase on the thickness of the substrate of the LED dies 211, can prevent electric arc damage to the connection. Therefore, the danger of leakage current can be prevented.

In conclusion, the packaging structure of AC LEDs of the present invention can pass the impact test of high voltage by use of the die-bonding insulating layer. Also, the die-bonding insulating layer can resist the external high voltage to improve the safety in operation. In addition, the die-bonding insulating layer of the present invention can be applied at a broad range of temperature and has good stability. Therefore, the product stability of the packaging structure of AC LEDs of the present invention is commercially attractive.

Although the present invention has been explained in relation to its preferred embodiment, it is to be understood that many other possible modifications and variations can be made without departing from the scope of the invention as hereinafter claimed.

What is claimed is:

1. A packaging structure of AC LEDs, comprising:
a carrier containing a positive electrode connecting end, and a negative electrode connecting end;
an AC LED module disposed on the carrier, wherein the AC LED module electrically connects to the positive electrode connecting end and the negative electrode connecting end of the carrier; and
a die-bonding insulating layer disposed between the AC LED module and the carrier.

2. The packaging structure of AC LEDs as claimed in claim 1, wherein the AC LED module comprises plural LED dies connecting to each other.

3. The packaging structure of AC LEDs as claimed in claim 1, wherein the die-bonding insulating layer comprises plural die-bonding regions, and each die-bonding region respectively corresponds to one LED die.

4. The packaging structure of AC LEDs as claimed in claim 1, wherein the AC LED module electrically connects to the positive electrode connecting end and the negative electrode connecting end through conductive wires.

5. The packaging structure of AC LEDs as claimed in claim 2, wherein the LED dies connect in series to each other through conductive wire.

6. The packaging structure of AC LEDs as claimed in claim 1, further comprising a heat dissipating unit, wherein the heat dissipating unit is disposed under the AC LED module, and the die-bonding insulating layer is arranged between the heat dissipating unit and the AC LED module.

7. The packaging structure of AC LEDs as claimed in claim 2, wherein the thickness of the LED dies is 100˜200 μm.

8. The packaging structure of AC LEDs as claimed in claim 1, wherein the thickness of the die-bonding insulating layer is 50˜120 μm.

9. The packaging structure of AC LEDs as claimed in claim 1, wherein the die-bonding insulating layer is a die-bonding silicone layer.

10. The packaging structure of AC LEDs as claimed in claim 1, wherein the hardness of the die-bonding insulating layer is 50˜60 Shore D, the modules of elasticity of the die-bonding insulating layer is 170˜190 N/mm², and the density of the die-bonding insulating layer is 1.0˜1.2 g/cm³.

11. The packaging structure of AC LEDs as claimed in claim 1, wherein the light transmissivity of the die-bonding insulating layer is 1.5˜3%.

12. The packaging structure of AC LEDs as claimed in claim 1, wherein the linear expansion coefficient of the die-bonding insulating layer is 200˜230 ppm.

13. The packaging structure of AC LEDs as claimed in claim 1, wherein the thermal conductivity of the die-bonding insulating layer is 0.15˜0.22 W/m·K.

14. The packaging structure of AC LEDs as claimed in claim 1, wherein the dielectric breakdown voltage of the die-bonding insulating layer is 23˜28 kV/mm.
